(19) United States
(12) Patent Application Publication
(10) Pub. No.: US 2010/0092686 A1
(43) Pub. Date: Apr. 15, 2010

(54) METHOD FOR THE PRODUCTION OF A COATING MATERIAL

(76) Inventors: Nora Laryea, Saarbruecken (DE); Carolin Thurn, Wadgassen (DE); Stefan Sepeur, Wadgassen (DE)

Correspondence Address: COLLARD & ROE, P.C., 1077 NORTHERN BOULEVARD, ROSLYN, NY, 11576, US

(21) Appl. No.: 12/451,131

(22) PCT Filed: Apr. 28, 2008
(86) PCT No.: PCT/DE2008/000586

§ 371 Date: Nov. 30, 2009

(30) Foreign Application Priority Data
Apr. 27, 2007 (DE) 10 2007 020 404.5

(51) Int. Cl. B05D 1/04; C09D 183/04; C09D 189/00; C23C 16/44; B05D 3/06

(52) U.S. Cl. 427/458; 524/588; 106/287.1; 106/287.11; 106/162.1; 106/124.1; 106/14.05; 106/15.05; 427/248.1; 427/558

(57) ABSTRACT

The invention relates to a method for producing a coating material as well as the use of the coating material.

In order to provide a method for producing a novel coating material with which scratchproof coatings can be fabricated and which may also be used as coating powder, it is proposed within the scope of the invention that one or more organic molecules, oligomers or polymers comprising at least one functional group react with one or more silanes comprising at least one functional organic group on an organic side chain to form a covalent bond between the organic molecule, oligomer or polymer and the silane, thus resulting in a high-molecular-weight silane which can be cured directly by means of a catalyst.

Surprisingly, it has been found that by reacting organically functionalized silanes, e.g. silanes that have an NCO— functional group (and are, at the most, slightly pre-crosslinked), with suitable reaction partners, a novel class of compounds can be produced which, in the form of coating powders, high-solids binders or 100 percent resins, may be used as coating material.

The invention relates to a method for producing a coating material as well as the use of said coating material.

Polysiloxane-based coating powders are known which crosslink via the functional organic groups (OH—, COOH—, NCO—) with suitable compounds and/or catalysts. Coating systems of this kind are used as anti-corrosion coatings for metals and are known, for example, from the U.S. Pat. No. 6,376,607 B1.

These coating systems show good corrosion resistance but mostly only moderate abrasion resistance.

Alternative coating powders include epoxy- or acrylate-modified polymers which are cross-linked by means of suitable catalysts and are used, for example, as clear coats for automobile applications. However, these coating systems, which are known, for example, from the U.S. Pat. No. 6,376,608 B1, show only moderate resistance to chemicals and moderate scratch resistance.

For scratchproof binders, the WO 2006/042658 A1, for example, also describes reactions of isocyanates (HDI) with aminofunctional silanes, which are cross-linked, for example, with suitable catalysts. However, these are dissolved in aprotic solvents or aprotic solvent mixtures only.

The US 2002/0042461 A1 describes a composition comprising at least one cyclic olefin addition polymer and containing, amongst other things, an organic carboxylic acid, organic phosphoric acid, organic sulphonic acid, ammonia, primary to tertiary amine compounds, or a quaternary ammonium hydroxide compound. The composition exhibits optical transparency, solvent resistance, heat resistance, and good adhesion to metals and inorganic substances. The object of the invention is to devise a method for producing a novel coating material in the form of a coating powder, with which scratchproof coatings may be produced.

This object is established according to the invention by a method for producing a coating material, in which one or more organic molecules, oligomers or polymers comprising at least one functional group reacts with a silane comprising at least one functional organic group on an organic side chain to form a covalent bond between the organic molecule, oligomer or polymer and the silane, thus resulting in a high-molecular-weight silane which can be cured directly by means of a catalyst.

According to the invention, the resultant compositions are in the form of coating powder or free-flowing resin.

Surprisingly, it has been found that by reacting (at the most, slightly pre-crosslinked) organically functionalized silanes, e.g. silanes with an NCO— functional group, with suitable reaction partners, a novel class of compounds can be produced which, in the form of coating powders, high-solids binders or 100 percent resins, may be used as coating material. According to the prior art, silanes are processed via sol-gel processes, starting from pre-condensed species. The method of the invention, in which a pre-condensation reaction is largely or entirely avoided, has the advantage that there are no longer any restrictions with regard to the pot life and that, in addition, better coating-material properties can be achieved, in particular high scratch resistance. The high-molecular-weight silanes obtained may either be in the form of a solid, which is remeltable at temperatures above 80° C., or a 100 percent resin that is still free-flowing.

The invention provides for at least 20%, preferably all, of the functional organic groups on the molecule, oligomer or polymer to lose their reactivity by way of a reaction with an organic functional group on a silane.

The former variant is particularly useful if the remaining functional groups perform a function, for example an antimicrobial, germ-resistant, hormonal or enzymatic function, or act biochemically in some other way.

Preferred embodiments of the invention consist in that the organic molecule, oligomer or polymer is selected from the group consisting of alcohols, polyols, amines, isocyanates, hydrogen sulphide compounds, phosphates, anhydrides, carboxylic acids, methacrylates, acrylates, amino acids or DNA, hormones, enzymes, peptides, sugars, polysaccharides, biomedical active ingredients and natural substances.

Preferred embodiments of the invention consist in that the silanes with a functional group on the organic side chain are selected from the group consisting of monoamine-functionalized silanes (trialkoxy, dialkoxy, monoalkoxy), diamine-functionalized silanes (trialkoxy, dialkoxy, monoalkoxy), triamine-functionalized silanes, sec-amine-functionalized silanes, tert-amine-functionalized silanes, quat-amine-functionalized silanes, dipodal-amine funktionalized silanes, anhydride-functionalized silanes, acrylate- and methacrylate-functionalized silanes (trialkoxy, dialkoxy, monoalkoxy), epoxy-functionalized silanes (trialkoxy, dialkoxy, monoalkoxy), halogen-functionalized silanes (trialkoxy, dialkoxy, monoalkoxy), isocyanate-functionalized and masked-isocyanate-functionalized silanes, phosphate-functionalized silanes, sulphur-functionalized silanes, vinyl- and olefin-functionalized silanes (trialkoxy, dialkoxy, monoalkoxy) and trimethoxysilylpropyl-modified polyethylenimins.

The following silanes are particularly suitable: 3-aminopropyltriethoxysilane, aminoethylaminpropyltrimethoxysilane, aminoethylaminopropyltrimethoxysilane, aminoethylaminopropylsilane, 3-aminopropyltrimethoxysilane, N-(2-aminoethyl)-3-aminopropyltrimethoxysilane, N-(2-aminoethyl)-3-aminopropylmethyldimethoxysilane, N-(2-aminoethyl)-3-aminopropylmethyldimethoxysilane, N-cyclohexyl-3-aminopropyl-trimethoxysilane, benzylaminoethylaminopropyltrimethoxysilane, vinylbenzylamino-ethylaminopropyltrimethoxysilane, vinyltrimethoxysilane, vinyltriethoxysilane, vinyldimethoxymethylsilane, vinyl(tris)methoxyethoxy)silane, vinylmethoxymethylsilane, vinyltris(2-methoxyethoxy)silane, vinyltriacetoxysilane, chloropropyltrimethoxysilane, 3-glycidoxypropyltrimethoxysilane, 3-glycidoxypropyltriethoxysilane, glycidoxypropyl-methyldiethoxysilane, mercaptopropyl-trimethoxysilane, bis-triethoxysilylpropyldisulphidosilane, bis-triethoxysilyl-propyldisulphidosilane, bis-triethoxysilylpropyltetrasulphidosilane, N-cyclohexylaminomethylmethyldieethoxysilane, N-cyclohexylaminomethyltriethoxysilane, N-phenylaminomethyltrimethoxysilane, (methacryloxymethyl)methyldimethoxysilane, methacryl-oxymethyltrimethoxysilane, (methacryloxymethyl)methyldiethoxysilane, methacryloxymethyl-triethoxysilane, 3-methacryloxypropyltrimethoxysilane, 3-methacryloxypropyltrimethoxysilane, 3-methacryloxypropyltriacetoxysilane, (isocyanatomethyl)methyldimethoxysilane, 3-isocyanatopropyltrimethoxysilane, 3-isocyanatopropyltriethoxysilane, 3-trimethoxysilylmethyl-O-methylcarbamate, N-dimethoxy-(methyl)silylmethyl-O-methyl-carbamate, 3-(triethoxysilyl)propylsuccinic anhydride, dicyclopentyldimethoxysilane and 3-(trimethoxysilyl)-propyldimethyloctadecylammonium chloride, tris(3-trimethoxysily)isocyanurate, 3-triethoxysilylpropyl)-t-butylcarbamate, triethoxysilylpropylethylcarbamate, 3-thiocyanatopropyltriethoxysilane, bis [3-(triethoxysily)propyl]-tetrasulphide, bis [3-(triethoxysilyl)propyl]-disulphide, 3-mercaptopropylmethyldimethoxysilane.

It is within the scope of the invention that the water content is 1% at the most, and, particularly preferred, that the reaction is conducted in the absence of water. As a rule, the moisture in the air does not interfere with the reaction.

It has proved advantageous that the resultant composition, which is again a silane, has a molar mass of at least 500 g/mol.

In this connection, the invention provides for the silane or silanes to be pre-crosslinked to a maximum extent of 5%, preferably 1%, and, particularly preferably, for the pre-crosslinking to be non-inorganic.

It is also within the scope of the invention that the organic molecule is selected from the group consisting of alcohols, amines, isocyanates, hydrogen sulphide compounds, phosphates, anhydrides, carboxylic acids, amino acids, hormones, enzymes, peptides, sugars, polysaccharides, and natural substances.

An embodiment of the invention consists in that the reaction product is dissolved in protic or aprotic solvents.

This makes subsequent application by means of a wet-chemical coating process possible.

It may be to advantage, for example, to add solvents, especially alcohols, acetates, ethers or reaction diluents.

It is expedient here that dissolution is effected by heating to at least 50° C.

A development of the invention consists in that up to 20 wt. %, preferably 0.5 to 50 wt. %, of silanes, particularly aminosilanes, or Lewis acids or Lewis bases, particularly in the form of transition-metal complexes, transition-metal salts or transition-metal particles, preferably microparticles or nanoparticles, are used as catalysts.

In this connection, it is preferable for the transition-metal complexes, salts or particles to be complexes of titanium, aluminium, tin or zirconium.

Provision may also be made for inorganic or organic particles, in particular micro-, submicro- or nanoparticles, to be added as fillers.

The invention also provides for the addition of matting agents, wetting dispersants, UV absorbers, UV stabilizers, HALS stabilizers, free-radical scavengers, defoaming agents, waxes, biocides, preservatives, inorganic or organic fillers, Teflon particles, waxes or pigments.

It is furthermore within the scope of the invention that the coating material can be applied to a substrate electrostatically, triboelectrically or by a wet-chemical process, in particular by spraying, dipping, flooding, roll-coating, brushing, printing, spin-coating, by doctor knife or by vaporising under vacuum.

According to the invention, the substrate in this connection consists of metal, plastic, ceramic, coating substance, fabric, textiles, natural substances such as wood and leather, glass, mineral substances, in particular synthetic or natural stones such as marble and granite, or composite materials.

A development of the method according to the invention consists in that, following application, the coating material is curable at temperatures in the range from room temperature to 1,200° C., preferably 50° C. to 250° C., curing preferably being effected thermally, by microwave radiation or by UV radiation.

Another development of the invention consists in that curing is effected at room temperature by the addition of organic acids or bases or with UV light by way of free-radical or cationic polymerisation following addition of photoinitiators for free-radical or cationic polymerisation.

The scope of the invention also includes use of the coating material produced according to the invention for making scratchproof, anticorrosion, easy-to-clean, antifingerprint, antireflection, antifogging, antiscaling, antifouling, diffusion-barrier, wood-protection and radiation-protection coatings, or as self-cleaning, antibacterial, antimicrobial, chemical-resistant, tribological or hydrophilic coatings, and in biomedical applications, in particular for promoting tissue growth and for influencing blood clotting, and for the treatment of tissue and implants.

The invention is explained in detail below by reference to embodiments.

### EXAMPLE 1

Stage 1:

11.8 g hexandiol and 49.5 g ICTES (isocyanatopropyltriethoxysilane) are stirred and heated together to a temperature of 80° C.; 0.1 g dibutyltindilaurate are added. The mixture is then left to cool to 50° C. before being processed further according to methods A and B.

Stage 2, Method A (Coating Powder Formulation):

10 g reaction product are mixed at this temperature with 0.1 g aluminiumacetylacetonate (50% dissolved in 2-butanol). This mixture is then cooled down slowly to room temperature. The resin that subsequently crystallizes out is then crushed in a special mill to a grain size of <50 μm and sieved. Byk 359 (0.8%) is added to the powder as a flow-control agent and mixed in thoroughly.

The powder produced in this way is then applied by electrostatic or triboelectrical spraying to a colour-coated steel sheet, and is dried at 130° C. in an oven with forced-air circulation.

Stage 2, Method B (High-solids Formulation):

80 g of the reaction product are dissolved in 20 g 1-methoxy-2-propanol. To this solution, 0.2 g aluminiumacetylacetonate are added. Following spray-application onto a steel plate provided with a black-pigmented base coating, the coating material is cured for 20 minutes at 150° C. in a convection oven.

The specimens provided with the coating obtained by methods A and B show excellent scratch resistance towards steel wool, as well as chemical resistance: no damage (no etching) was done by >30 minutes' treatment with 36% sulphuric acid.

### EXAMPLE 2

Stage 1:

33.6 g 2,2-bis(4-hydroxyphenylhexafluoropropane and 49.47 g ICTES (isocyanatopropyltriethoxysilane) are stirred and heated together to a temperature of 80° C.; 0.1 g dibutyltindilaurate are added. The mixture is then left to cool to 50° C. before being processed further in stage 2.

Stage 2:

5 g of the reaction product (from stage 1) are dissolved in 1 g isopropanol and mixed with 0.1 g zirconiumacetylacetonate.

The coating solution obtained is used to coat polycarbonate substrates by flooding, and is then cured at 130° C. for 60 minutes in a convection oven. Prior to application of the coating solution, the polycarbonate substrates are flood-coated with a primer (0.5% 3-aminopropyltriethoxysilane solution in ethanol) and left at room temperature for 5 minutes to permit flash-off.

The coatings show very high resistance to localized scratching, for example by keys or screwdrivers. In the QUV test, the coatings showed no optically visible yellowing after 1,000 h.

### EXAMPLE 3

Stage 1:

1 mole Fluorolink D (_{HOCH}₂CF₂—O—(CF₂CF₂O)ₚ—(CF₂O)_{q}—CF₂—CH₂OH from Ausimont) is heated with 2 moles isocyanatopropyltriethoxysilane (ICTES) to at least 80° C. until a homogeneous, transparent mixture is obtained. Two drops of dibutyltinlaurate are then added, and the mixture stirred for a further 3 h. The mixture is subsequently cooled to room temperature.

Stage 2:

3 g of the wax-like mixture are then mixed with 0.1 g zirconium lactate and 9 g ethanol. The mixture is then sprayed onto a degreased and oil-free stainless-steel plate and cured at 180° C. for 1 h in a drying cabinet.

After contact with a finger greased with Nivea cream, the coated surface shows a clearly less visible fingerprint than an untreated surface. After 1 h, the fingerprint is wiped off with a dry paper towel. Compared again to the reference specimen, the fingerprint is removed much more effectively, with no residue remaining. On the untreated surface, the fingerprint is still visible after wiping. Next, the surface is treated with cooking oil and water. Compared to an untreated stainless-steel surface, it shows pronounced droplet formation. The droplets can be removed very easily with a dry cloth, leaving no residue.

### EXAMPLE 4

mole H[O(CH₂)₄]nOH (PolyTHF 2000 from BASF) is heated with 2 moles isocyanatopropyltriethoxysilane (ICTES) until a homogeneous, transparent mixture is obtained. Two drops of dibutyltinlaurate are then added, and the mixture stirred for a further 8 h. The mixture is subsequently cooled to room temperature.

Next, the mixture is applied to a polycarbonate plate by dipping, and then dried at 130° C. The coated specimen is placed flat at a distance of 15 cm above a pot of boiling water and observed for 20 s. In this test, there was no misting on the coated side of the plate.

1-16. (canceled)

17. Method for producing a coating material, wherein one or more organic molecules, oligomers or polymers comprising at least one functional group reacts with one or more silanes comprising at least one functional organic group on an organic side chain to form a covalent bond between the organic molecule, oligomer or polymer and the silane, thus resulting in a high-molecular-weight silane which can be cured directly by means of a catalyst, at least 20% of the functional organic groups on the molecule, oligomer or polymer losing their reactivity by way of a reaction with an organic functional group on a silane and the resultant compositions being in the form of coating powder or free-flowing resin.

18. Method according to claim 17, wherein all the functional organic groups on the molecule, oligomer or polymer lose their reactivity by way of a reaction with an organic functional group on a silane.

19. Method according to claim 17, wherein the organic molecule, oligomer or polymer is selected from the group consisting of alcohols, polyols, amines, isocyanates, hydrogen sulphide compounds, phosphates, anhydrides, carboxylic acids, methacrylates, acrylates, amino acids or DNA, hormones, enzymes, peptides, sugars, polysaccharides, biomedical active ingredients and natural substances.

20. Method according to claim 17, wherein the silanes with a functional group on the organic side chain are selected from the group consisting of monoamine-functionalized silanes (trialkoxy, dialkoxy, monoalkoxy), diamine-functionalized silanes (trialkoxy, dialkoxy, monoalkoxy), triamine-functionalized silanes, sec-amine-functionalized silanes, tert-amine-functionalized silanes, quat-amine-functionalized silanes, dipodal-amine funktionalized silanes, anhydride-functionalized silanes, acrylate- and methacrylate-functionalized silanes (trialkoxy, dialkoxy, monoalkoxy), epoxy-functionalized silanes (trialkoxy, dialkoxy, monoalkoxy), halogen-functionalized silanes (trialkoxy, dialkoxy, monoalkoxy), isocyanate-functionalized and masked-isocyanate-functionalized silanes, phosphate-functionalized silanes, sulphur-functionalized silanes, vinyl- and olefin-functionalized silanes (trialkoxy, dialkoxy, monoalkoxy) and trimethoxysilylpropyl-modified polyethylenimins.

21. Method according to claim 17, wherein the resultant compositions have a molar mass of at least 500 g/mol.

22. Method according to claim 17, wherein the resultant compositions are dissolved in protic or aprotic solvents.

23. Method according to claim 17, wherein up to 20 wt. %, preferably 0.5 to 50 wt. %, of silanes, particularly aminosilanes, or Lewis acids or Lewis bases, particularly in the form of transition-metal complexes, transition-metal salts or transition-metal particles, preferably microparticles or nanoparticles, are used as catalysts.

24. Method according to claim 23, wherein the transition-metal complexes, salts or particles are complexes of titanium, aluminium, tin or zirconium.

25. Method according to claim 17, wherein inorganic or organic particles, in particular micro-, submicro- or nanoparticles, are added as fillers.

26. Method according to claim 17, wherein matting agents, wetting dispersants, UV absorbers, UV stabilizers, HALS stabilizers, free-radical scavengers, defoaming agents, waxes, biocides, preservatives, inorganic or organic fillers, fluorocarbon particles, waxes or pigments are added.

27. Method according to claim 17, wherein the coating material is applied to a substrate electrostatically, triboelectrically or by a wet-chemical process, in particular by spraying, dipping, flooding roll-coating, brushing, printing, spin-coating, by doctor knife or by vaporizing under vacuum.

28. Method according to claim 27, wherein the substrate consists of metal, plastic, ceramic, coating substance, fabric, textiles, natural substances such as wood and leather, glass, mineral substances, in particular synthetic or natural stones such as marble and granite, or composite materials.

29. Method according to claim 27, wherein following application, the coating material is curable at temperatures in the range from room temperature to 1,200° C., preferably from room temperature to 250° C., curing preferably being effected thermally, by microwave radiation, electron radiation, UV radiation or combinations thereof.

30. Method according to claim 29, wherein curing is effected at room temperature by the addition of organic acids or bases or with UV light by way of free-radical or cationic polymerization following addition of photoinitiators for free-radical or cationic polymerization.

31. Use of the coating material produced according to claim 17 for fabricating scratchproof, anticorrosion, easy-to-clean, antifingerprint, antireflection, antifogging, antiscaling, antifouling, wood-protection, diffusion-barrier, and radiation-protection coatings, or as self-cleaning, antibacterial, antimicrobial, chemical-resistant, tribological or hydrophilic coatings, and in biomedical applications, in particular for promoting the growth of tissues and for influencing blood clotting, and for the treatment of tissue and implants.
